(19) United States
(12) Patent Application Publication
(10) Pub. No.: US 2006/0131670 A1
(43) Pub. Date: Jun. 22, 2006

(54) Semiconductor device and production method therefor

(76) Inventors: Takashi Ogura, Tokyo (JP); Nobuyuki Ikarashi, Tokyo (JP); Toshiyuki Iwamoto, Tokyo (JP); Hirohito Watanabe, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 10/561,608

(22) PCT Filed: Apr. 26, 2004
(86) PCT No.: PCT/JP04/05997

§ 371 Date: Dec. 20, 2005

(30) Foreign Application Priority Data
Jun. 20, 2003 (JP) 2003-176582

(51) Int. Cl. H01L 29/76

(52) U.S. Cl. 257/406

(57) ABSTRACT

A semiconductor device provided with a MIS type field effect transistor comprising a silicon substrate, a gate insulating film having a high-dielectric-constant metal oxide film which is formed on the silicon substrate via a silicon containing insulating film, a silicon-containing gate electrode formed on the gate insulating film, and a sidewall including, as a constituting material, silicon oxide on a lateral face side of the gate electrode, wherein a silicon nitride film is interposed between the sidewall and at least the lateral face of the gate electrode. This semiconductor device, although having a fine structure with a small gate length, is capable of low power consumption and fast operation.

### TECHNICAL FIELD

The present invention relates to a semiconductor device and a production method therefor, and more particularly to a semiconductor device having a MIS type field effect transistor (MISFET) wherein a film of a highly dielectric substance is used as a gate insulating film and a production method therefor.

### BACKGROUND ART

In recent years, for the purpose of providing the MOS type field effect transistor (MOSFET) with a higher operation speed, attempts to make the gate insulating film (SiO₂ film) thinner has been being made, achieving a thickness of 2 nm or so. Following this, however, the amount of the gate leakage current has become considerable, which is difficult to ignore from the viewpoint of the power consumption. In order to reduce the amount of this gate leakage current, the use of a material (a High-K material) having a higher dielectric constant than SiO₂ for the gate insulating film is under investigation. When a High-K material is employed for the gate insulating film, the device can attain fast operations because its conversion film thickness of the SiO₂ film can be made thin, and, at the same time, the amount of the gate leakage current can be reduced because its physical film thickness can be kept considerably thick.

As the High-K material, metal oxides such as hafnium oxide (HfO₂) and zirconium oxide (ZrO₂) and metal oxides in which silicon or the like is further contained in one of the foregoing metal oxides (compositional formula: HfSiO, ZrSiO and the like) are known.

One example of the MISFET wherein such a High-K material is used as a gate insulating film is disclosed in Japanese Patent Application Laid-open No. 134739/2002. A MISFET described in that publication has a gate insulating film with a three-layered structure of a lower layer section, a central section and an upper layer section, wherein with respect to the silicon substrate the lower layer section has a lower reactivity than the central section, and with respect to the gate electrode (the polysilicon electrode) the upper layer section has a lower reactivity than the central section. More specifically, a HfSiO₂ film is utilized for each of the upper layer section and the lower layer section, whereas a HfO₂ film is employed for the central section. Further, it is described therein that a structure of this sort enables to reduce power consumption and provide fast operations.

However, even with the structure designed in due consideration for the reactivities of the High-K materials as in the afore-mentioned conventional technique, when the gate length becomes shortened further along with the miniaturization of the device, there arises a problem that the operation current does not rise satisfactorily in comparison with the MOSFET wherein a silicon oxide film is used as the gate insulating film. In FIG. 1, the relationship between the gate length and the ON-current per unit channel width (Iₒₙ) is shown. Herein, the Si mole ratios (Si/(Si+Hf) in HfSiO (A) and in HfSiO (B) are 30% and 13%, respectively. As seen clearly in this diagram. when the HfSiO film is used as the gate insulating film, with shortening the gate length, the value of the ON-current falls further down from the value of the ON-current when the SiO₂ film is used. Further, it is evidently shown that if the Si content ratio in the HfSiO film is low, the drop of the ON-current is more marked. Because the fact that the lower the Si content ratio is, the more the ON-current falls down trade off another fact that the lower the Si content ratio is, the higher the dielectric constant becomes, substantial difficulties are brought about in respect of achieving fast operations.

### DISCLOSURE OF THE INVENTION

An object of the present invention is to provide a semiconductor device comprising a MISFET which is capable of fast operation with low power consumption while having a minute structure with a short gate length and a production method therefor.

The present invention comprises embodiments each described in the following Items 1-24.

1. A semiconductor device comprising a MIS type field effect transistor, wherein the transistor comprising:

a silicon substrate;

a gate insulating film comprising a high-dielectric-constant metal oxide film and a silicon containing insulating film lying between the metal oxide film and the silicon substrate;

a silicon containing gate electrode formed on the gate insulating film; and

a sidewall including silicon oxide as a constituting material, which is formed on each lateral face side of the gate electrode; and

wherein a silicon nitride film is interposed between the sidewall and at least the lateral face of the gate electrode.

2. The semiconductor device comprising the MIS type field effect transistor as described in Item 1, wherein the silicon nitride film covers the lateral face of the high-dielectric-constant metal oxide film.

3. The semiconductor device as described in Item 1 or 2, wherein a silicon oxide film underlies the silicon nitride film.

4. A semiconductor device comprising a MIS type field effect transistor, wherein the transistor comprising:

a silicon substrate;

a gate insulating film comprising a high-dielectric-constant metal oxide film and a silicon containing insulating film lying between the metal oxide film and the silicon substrate; and

a silicon containing gate electrode formed on the gate insulating film; and

wherein the high-dielectric-constant metal oxide film has a nitrogen containing section at least on each of its lateral face sides.

5. The semiconductor device as described in Item 4, wherein the nitrogen-containing section is a silicon nitride film covering at least the lateral face of the high-dielectric-constant metal oxide film.

6. The semiconductor device as described in Item 5, wherein each lateral face of the gate insulating film has a recess with respect to the plane of the lateral face of the gate electrode, and, inside the recess, the silicon nitride film covers at least the lateral face of the high-dielectric-constant metal oxide film.

7. The semiconductor device as described in Item 4, wherein the nitrogen containing section is formed by applying a nitriding treatment to each lateral face section of the high-dielectric-constant metal oxide film.

8. The semiconductor device as described in any one of Items 4 to 7, which further comprising a sidewall including silicon oxide as a constituting material, which is formed on each lateral face side of the gate electrode.

9. The semiconductor device as described in any one of Items 1 to 8, wherein a silicon nitride films is laid between the high-dielectric-constant metal oxide film and the gate electrode.

10. The semiconductor device as described in any one of Items 1 to 9, wherein the high-dielectric-constant metal oxide film contains hafnium (Hf).

11. The semiconductor device as described in any one of Items 1 to 10, wherein a dielectric constant of the high-dielectric-constant metal oxide film is not less than 10.

12. The semiconductor device as described in any one of Items 1 to 3 and 8, wherein the high-dielectric-constant metal oxide film is absent beneath the sidewall.

13. The semiconductor device as described in any one of Items 1 to 12, wherein a gate length of the gate electrode is not greater than 1 μm.

14. A method of manufacturing a semiconductor device comprising the steps of:

forming a high-dielectric-constant metal oxide film over a silicon substrate after forming a silicon containing insulating film;

forming a film of a silicon containing gate electrode material over the high-dielectric-constant metal oxide film;

forming a gate electrode by patterning the film of a gate electrode material;

forming a pattern of the high-dielectric-constant metal oxide film under the gate electrode by patterning the high-dielectric-constant metal oxide film;

forming a silicon nitride film over the entire surface;

forming a silicon oxide film on the silicon nitride film; and

etching back the silicon oxide film and the silicon nitride film and thereby forming a sidewall on each lateral face of the gate electrode with the silicon nitride film lying therebetween.

15. The method of manufacturing a semiconductor device as described in Item 14, further comprising, after the step of forming the silicon nitride film, the step of applying etch back to the silicon nitride film so that the silicon nitride film lying on the gate electrode and the silicon substrate can be removed, following which the silicon oxide film is formed over the entire surface and by etching back the silicon oxide film, a sidewall is formed on each lateral face of the gate electrode.

16. A method of manufacturing a semiconductor device comprising the steps of:

forming a high-dielectric-constant metal oxide film over a silicon substrate after forming a silicon containing insulating film;

forming a film of a silicon containing gate electrode material over the high-dielectric-constant metal oxide film;

forming a gate electrode by patterning the film of a gate electrode material;

forming a pattern of the high-dielectric-constant metal oxide film and the silicon containing insulating film under the gate electrode by patterning the high-dielectric-constant metal oxide film and the silicon containing insulating film;

forming a first silicon oxide film over the entire surface at a temperature of not higher than 600° C.;

forming a silicon nitride film on the first silicon oxide film;

forming a second silicon oxide film on the silicon nitride film; and

etching back the second silicon oxide film, the silicon nitride film and first silicon oxide film and thereby forming a sidewall on each lateral face of the gate electrode with the first silicon oxide film and the silicon nitride film lying therebetween.

17. The method of manufacturing a semiconductor device as described in Item 16, further comprising, after the step of forming the silicon nitride film, the step of applying etch back to the silicon nitride film and the first silicon oxide film so that the silicon nitride film and the silicon oxide film lying on the gate electrode and the silicon substrate can be removed, following which the second silicon oxide film is formed over the entire surface and by etching back the second silicon oxide film, a sidewall is formed on each lateral face of the gate electrode.

18. A method of manufacturing a semiconductor device comprising the steps of:

forming a high-dielectric-constant metal oxide film over a silicon substrate after forming a silicon containing insulating film;

forming a film of a silicon containing gate electrode material over the high-dielectric-constant metal oxide film;

forming a gate electrode by patterning the film of a gate electrode material;

forming a pattern of the high-dielectric-constant metal oxide film under the gate electrode by patterning the high-dielectric-constant metal oxide film;

removing at least each lateral face section of the pattern of the high-dielectric-constant metal oxide film by means of isotropic etching to form a recess;

forming a silicon nitride film over the entire surface so as to fill up the recess;

etching the silicon nitride film in such a way that, inside the recess, at least the silicon nitride film covering each lateral face of the high-dielectric-constant metal oxide film can remain; and

forming a silicon oxide film over the entire surface and then etching back the silicon oxide film, and thereby forming a sidewall on each lateral face of the gate electrode.

19. A method of manufacturing a semiconductor device comprising the steps of:

forming a high-dielectric-constant metal oxide film over a silicon substrate after forming a silicon containing insulating film;

forming a film of a silicon containing gate electrode material over the high-dielectric-constant metal oxide film;

forming a gate electrode by patterning the film of a gate electrode material;

forming a pattern of the high-dielectric-constant metal oxide film under the gate electrode by patterning the high-dielectric-constant metal oxide film;

applying a nitriding treatment to each lateral face section of the pattern of the high-dielectric-constant metal oxide film; and

forming a silicon oxide film over the entire surface and then etching back the silicon oxide film, and thereby forming a sidewall on each lateral face of the gate electrode.

20. A method of manufacturing a semiconductor device comprising the steps of:

forming a high-dielectric-constant metal oxide film over a silicon substrate after forming a silicon containing insulating film;

forming a film of a silicon containing gate electrode material over the high-dielectric-constant metal oxide film;

forming a gate electrode by patterning the film of a gate electrode material;

forming a pattern of the high-dielectric-constant metal oxide film under the gate electrode by patterning the high-dielectric-constant metal oxide film;

forming a silicon oxide film over the entire surface at a temperature of not higher than 600° C.; and

etching back the silicon oxide film, and thereby forming a sidewall on each lateral face of the gate electrode.

21. The method of manufacturing a semiconductor device as described in any one of Items 14, 15 and 18 to 20, wherein a pattern of the silicon containing insulating film is further formed under the gate electrode by patterning the silicon containing insulating film.

22. The method of manufacturing a semiconductor device as described in any one of Items 14 to 21, wherein the high-dielectric-constant metal oxide film contains hafnium (Hf).

23. The method of manufacturing a semiconductor device as described in any one of Items 14 to 22, wherein a dielectric constant of the high-dielectric-constant metal oxide film is not less than 10.

24. The method of manufacturing a semiconductor device as described in any one of Items 14 to 23, wherein a gate length of the gate electrode is not greater than 1 μm.

A high-dielectric-constant metal oxide film as used in the present invention refers to one having a higher dielectric constant than SiO₂, and therefor a film made of metal oxide whose dielectric constant is preferably not lower than 7 and more preferably not lower than 10 is employed.

In the present invention, there is provided a semiconductor device which comprises a MISFET capable of fast operation with low power consumption while having a minute structure with a short gate length.

### BRIEF DESCRIPTION OF THE DRAWINGS

FIG. 1 is a diagram showing the relationship between the gate length and the ON-current per unit channel width (Iₒₙ) in the conventional MISFET.

FIG. 2 is a schematic cross-sectional view showing one example of the MISFET in accordance with the present invention.

FIG. 3 is a schematic cross-sectional view showing another example of the MISFET in accordance with the present invention.

FIG. 4 is a series of schematic cross-sectional views illustrating a method of manufacturing a MISFET in accordance with the present invention.

FIG. 5 is a schematic cross-sectional view showing another example of the MISFET in accordance with the present invention.

FIG. 6 is a schematic cross-sectional view showing another example of the MISFET in accordance with the present invention.

FIG. 7 is a schematic cross-sectional view in explaining the step of a method of manufacturing a MISFET in accordance with the present invention.

FIG. 8 is a schematic cross-sectional view showing another example of the MISFET in accordance with the present invention.

FIG. 9 is a series of schematic cross-sectional views in explaining the steps of a method of manufacturing a MISFET in accordance with the present invention.

FIG. 10 is a schematic cross-sectional view showing another example of the MISFET in accordance with the present invention.

FIG. 11 is a schematic cross-sectional view in explaining the step of a method of manufacturing a MISFET in accordance with the present invention.

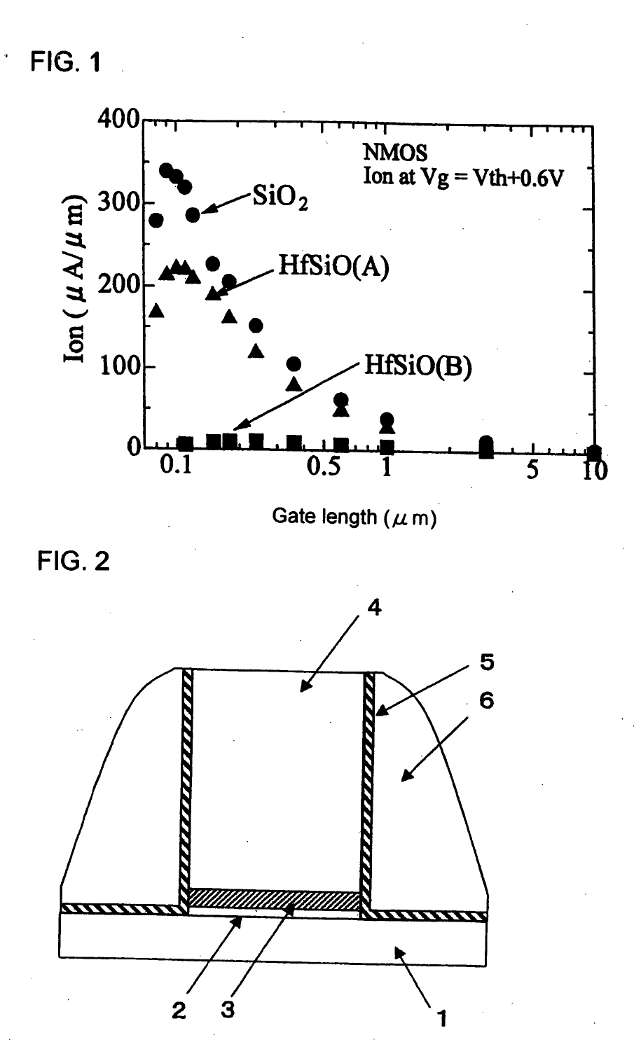

### BEST MODE FOR CARRYING OUT THE INVENTION

While conducting investigations to develop the semiconductor device comprising the MISFET capable of fast operation with low power consumption, the present inventors found out that, as described above, the FET wherein the High-K material is used for the gate insulating film, as compared with that with the silicon oxide film being utilized, has a problem that the rise of the operation current (Iₒₙ) becomes more suppressed, with shortening the gate length. This problem is evident particularly in the case that a specific device structure is taken, namely, a structure in which the gate length is short (especially when 1 μm or shorter) and besides a sidewall made of silicon oxide is set on each lateral face of the gate electrode. The close examinations revealed that this problem is brought about by the insulating films of about several nm thickness which are formed or additionally grown on the top and under surfaces of the high-dielectric-constant metal oxide film that constitutes the gate insulating film. These insulating films are thought to be silicon oxide films and the added portion of the films as much is considered to increase the electrical film thickness of the gate insulating film (increase the inversion capacitance) and, consequently, lower the operation current (Iₒₙ). Further, since the formation of these silicon oxide films becomes substantially marked after the step of forming the sidewalls, the main cause is presumably present in the film deposition performed in an oxidizing atmosphere in this step. In effect, it is thought to occur as follows. When the sidewalls are formed in an oxidizing atmosphere by the film deposition, from the exposed section of the high-dielectric-constant metal oxide film the oxidant such as oxygen penetrates and diffuses into the film, and this oxidant reacts with the silicon component of the gate electrode lying on the high-dielectric-constant metal oxide film and that of the underlying layer (or the silicon substrate), which leads to the formation of a silicon oxide film or the additional growth of the silicon oxide film. Further, for the reason why the operation current (Iₒₙ) is more suppressed with shortening the gate length, it can be given that when the gate length is short, the length of the high-dielectric-constant metal oxide film, which is formed beneath the gate electrode, along the direction of the gate length becomes also short, so that the oxidant can be readily diffuse even into the central section of the silicon oxide film and, therefore, the formation of a silicon oxide film or the additional growth of the silicon oxide film becomes more liable to occur over the entire region of the high-dielectric-constant metal oxide film along the direction of the gate length.

In light of the above problem, wide investigations were carried out to accomplish the present invention, the main feature of which is the structure capable to suppress, in the treatment performed, under heating, in an oxidizing atmosphere containing oxidants of oxygen and the like, the permeation and/or penetration of the oxidants into the high-dielectric-constant metal oxide film that constitutes the gate insulating film.

As described above, because the reduction of the operation current (Iₒₙ) becomes more marked with shortening the gate length, the present invention is particularly effective for the semiconductor device comprising the MISFET with a gate length of not greater than 1 μm, more effective with a gate length of not greater than 200 nm and still more effective with a gate length of not greater than 100 nm.

Further, from the point of view of suppressing the short channel effect, the present invention is particularly effective when the structure wherein the high-dielectric-constant metal oxide film constituting the gate insulating film is absent beneath the sidewalls or the structure wherein the high-dielectric-constant metal oxide film lies only in the region beneath the gate electrode is employed.

The main features characterizing the structure of one embodiment of the present invention are that a gate insulating film comprising a high-dielectric-constant metal oxide film and a silicon containing insulating film lying between the metal oxide film and a silicon substrate, a silicon containing gate electrode formed on this gate insulating film, and a sidewall including silicon oxide as a constituting material, which is formed on each lateral face side of this gate electrode are comprised, and that a silicon nitride film is interposed between the sidewall and at least the lateral face of the gate insulating film.

Further, the main features characterizing the structure of another embodiment are that a gate insulating film comprising a high-dielectric-constant metal oxide film and a silicon containing insulating film lying between the metal oxide film and a silicon substrate, and a silicon containing gate electrode formed on this gate insulating film are comprised, and that the high-dielectric-constant metal oxide film has a nitrogen containing section at least on each of its lateral face sides.

Further, the main features in process enabling to achieve such a characteristic structure of the present invention as described above are that after forming a gate electrode and a gate insulating film that comprises a high-dielectric-constant metal oxide film, a treatment is made under heating in an oxidizing atmosphere at a temperature of not higher than 600° C., while the high-dielectric-constant metal oxide film is exposed.

The preferred embodiments of the present invention are described in below.

It must be noted, herein, that the deep dopant diffusion regions to constitute the source/drain regions and the shallow dopant diffusion regions to constitute the LDD regions are both omitted in the drawings referred to in the following description.

### First Embodiment

In the present embodiment, as shown in FIG. 2, there are set, on a silicon substrate 1, a gate insulating film in which layers of a silicon containing insulating film 2 and a high-dielectric-constant metal oxide film 3 are laid in this order, a silicon containing gate electrode 4 formed on this gate insulating film, and sidewalls 6 each of which is formed on a lateral face of this gate electrode, the face of which is perpendicular to the substrate and includes a lateral face of this gate insulating film, with a silicon nitride film 5 lying therebetween. In this embodiment, each of the lateral faces (the faces perpendicular to the substrate) of the high-dielectric-constant metal oxide film 3 is covered with the silicon nitride film 5.

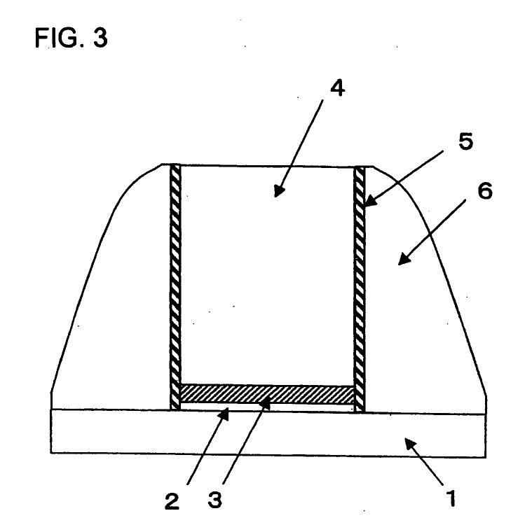

While the silicon nitride film 5 is laid beneath each sidewall 6 in the structure shown in FIG. 2, it is also possible to have the structure in which no silicon nitride film is present beneath the sidewall (between the sidewall and the silicon substrate) as shown in FIG. 3. Further, although in FIG. 2 and FIG. 3 the silicon nitride film 5 is in contact with the silicon substrate 1, it is preferable to interpose a silicon oxide film therebetween from the point of view of preventing the generation of an interface state.

In the structure of the present invention, for the high-dielectric-constant metal oxide film 3, metal oxides such as hafnium oxide (HfO₂) and zirconium oxide (ZrO₂) and metal oxides in which silicon (Si), aluminium (Al) or nitrogen (N) is further contained in one of the foregoing metal oxides (compositional formula: HfSiO, ZrSiO, HfAlO, ZrAlO, HfSiON and the like) can be utilized. Among them, HfSiO and HfSiON are preferable, viewed from the points of heat resistance and dielectric constant. Meanwhile, with regard to heat resistance, HfSiON that contains nitrogen is favoured. In respect of the device reliability, the nitrogen content (the ratio of the number of nitrogen atoms to the number of the whole constitutive atoms (percentage)) in the nitrogen containing metal oxide such as HfSiON is set preferably not higher than 50% and more preferably not higher than 40%. Further, the thickness of the high-dielectric-constant metal oxide film may be set approximately within a range of 0.5 nm to 10 nm, taking required device characteristics of power consumption, operation speed and such into consideration. Further, it is also possible to form the high-dielectric-constant metal oxide film with layers of two or more types of different compositions.

As the silicon containing insulating film 2 set beneath the high-dielectric-constant metal oxide film, a silicon oxide film (SiO₂ film), silicon oxynitride film (SiON film) or silicon nitride film (Si₃N₄ film) may be utilized. From the viewpoints of device characteristics such as reliability, a silicon oxide film is preferable. The thickness of this insulating film may be set appropriately within a range of 0.4 nm to 10 nm. If this insulating film is too thin, it cannot suppress the reaction between the high-dielectric-constant metal oxide film and the silicon substrate satisfactorily. If too thick, the electrical film thickness of the gate insulating film becomes too thick and the required operation speed cannot be attained.

The thickness of the silicon nitride film 5 covering the lateral face of the high-dielectric-constant metal oxide film may be set appropriately within a range possible to provide sufficient barrier function against the oxidants such as oxygen and, for instance, in a range of 1 nm to 10 nm. If the film is too thin, the required barrier function cannot be obtained and even the film cannot be grown uniformly. If too thick, on the other hand, there is a risk of lowering the reliability, resulting from an increase in stress.

The gate electrode 4 may be formed of polysilicon and its size can be set appropriately, as required. Nevertheless, as described above, the application of the present invention is effective if the gate length is not greater than 1 μm, more effective if not greater than 200 nm, and still more effective if not greater than 100 nm. On the other hand, from the viewpoints of required device characteristics and microfabrication accuracy, the gate length may be set appropriately in a range of preferably not less than 20 nm, and more preferably not less than 40 nm. The height of the gate electrode (the perpendicular measurement with respect to the substrate) may be set, for instance, in a range of 50 nm to 200 nm.

The sidewalls 6 may be formed of silicon oxide such as NSG, and its size can be set appropriately, depending on the size of the gate electrode.

Now, a method of manufacturing a MISFET of the present embodiment is described below.

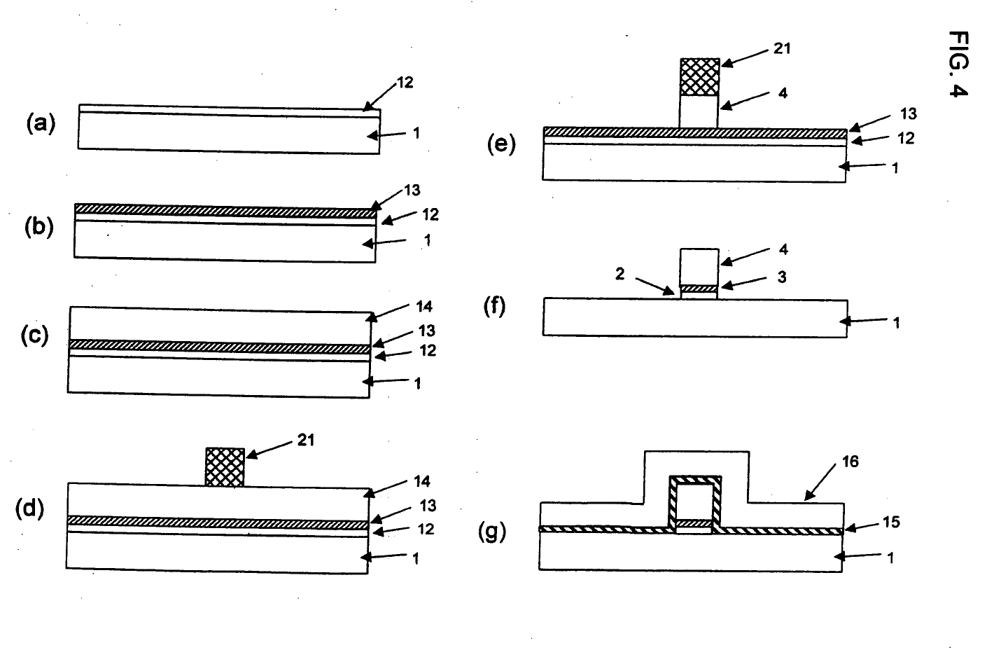

Firstly, after a silicon substrate 1 with an element isolation region (not shown in the drawings) is arranged, this substrate is cleaned with an acid solution such as a diluted aqueous solution of hydrofluoric acid to remove the natural oxidation film lying on the substrate surface, and then rinsed with pure water and dried. Following that, using the RTA method or the like, a thermal oxidation film 12 is formed on the substrate surface (FIG. 4(a)). The silicon containing insulating film 2 shown in FIG. 2 and FIG. 3 is formed of this thermal oxidation film 12. Alternatively, it is also possible to apply the nitriding treatment to this thermal oxidation film by a known method to form a silicon oxynitride film (SiON film). Further, in place of this thermal oxidation film 12, a silicon nitride film can be formed by a known method.

Next, on this thermal oxidation film 12, a HfSiO film 13 (or a HfSiON film) is formed as a high-dielectric-constant metal oxide film (FIG. 4(b)). For this, it is also possible to use a high-dielectric-constant metal oxide film with layers of two or more types of different compositions. As a method of growing the film, any well-known methods such as the solid phase diffusion method, the atomic layer growth method and the MOCVD method can be employed.

Next, on this HfSiO film 13 (or the HfSiON film), a polysilicon film 14 for the gate electrode formation is formed by the CVD method (FIG. 4(c)). With the object of providing the electrical conductivity, impurities are doped into this polysilicon film, while growing. Alternatively, the doping of impurities can be made after the film growth is completed.

Next, on this polysilicon film 14, a resist pattern 21 is formed (FIG. 4(d)), and then, using this resist pattern 21 as a mask, dry etching is carried out and the polysilicon film 14 is patterned to form a gate electrode 4 (FIG. 4(e)). Hereat, through an appropriate selection of the etching conditions to make the HfSiO film 13 (or the HfSiON film) function well as a stopper film, the etching may be made to stop, with a good accuracy, on the top surface of the HfSiO film 13 (or the HfSiON film). Further, it is also possible to use this dry etching to remove all of the HfSiO film 13 (or the HfSiON film) but a portion thereof lying beneath the gate electrode.

Next, after the resist pattern 21 is removed with a resist remover, the HfSiO film 13 (or the HfSiON film) and the thermal oxidation film 12 other than their sections lying beneath the gate electrode are removed with an insulating-film removing agent, and thereby a gate insulating film with a layered structure made of a silicon containing insulating film 2 (the thermal oxidation film) and a high-dielectric-constant metal oxide film 3 (the HfSiO film or the HfSiON film) is formed (FIG. 4(f)). This step of removing the insulating film may be performed, for example, under the following conditions. The conditions of removing the insulating film: An immersion in an aqueous solution of hydrofluoric acid (HF:H₂O=1:600 (weight ratio)) at 28° C. for a time period of 3 minutes.

Further, in this step of removing the film, the thermal oxidation film 12 can be made to remain on the substrate by selecting conditions (for instance, an immersion in an aqueous solution of hydrofluoric acid (HF:H₂O=1:2000 (weight ratio)) at 80° C. for a time period of 3 minutes) to make the etching rate of the thermal oxidation film 12 much smaller than that of the HfSiO film 13 (or the HfSiON film). In this case, a structure in which under the sidewall 6 the silicon nitride film 5 and the silicon substrate 1 sandwich a thermal oxidation film can be formed.

Further, in the step of cleaning, which is to be carried out following this step of removing the film, the natural oxidation film formed on the substrate can be left behind. In this case, a structure in which under the sidewall 6 the silicon nitride film 5 and the silicon substrate 1 sandwich a silicon oxide film may be formed.

Next, by doping impurities, a shallow diffusion layer with a relatively low dopant concentration is formed, in the manner of self alignment, to have the shape of the gate electrode.

Next, after a silicon nitride film 15 which is to be used as barriers to oxidants and a silicon oxide film 16 of NSG or the like which is to be used as sidewalls are laid in this order by the CVD method (FIG. 4(g)), an etch back is made by means of anisotropic etching, whereby sidewalls 6 overlying the silicon nitride films 5 are formed (FIG. 2). Meanwhile, by forming a silicon nitride film 15 and performing an etch back first and thereafter forming a silicon oxide film 16 and applying another etch back to this film, such a structure as shown in FIG. 3, in which silicon nitride films are absent beneath the sidewalls, can be formed. The deposition of the silicon oxide film by the CVD method may be conducted at a temperature, for example, exceeding 600° C. but not 1000° C., and preferably exceeding 600° C. but not 800° C.

Next, by doping impurities, a deep diffusion layer with a relatively high dopant concentration is formed, in the manner of self alignment, to have the shape of the gate electrode and sidewalls.

In the afore-mentioned steps and the subsequent steps, various treatments according to known methods are carried out, as a prescribed structure requires, and the formation of a MISFET structure may be accomplished.

In the present embodiment, because a silicon oxide film 16 which is to be used as sidewalls is formed after a silicon nitride film 15 which is to be used as barriers to oxidants is formed, even if the deposition in the step of growing the silicon oxide film is carried out in an environment that is set, from the viewpoints of the film growth rate and film quality, to have a relatively high temperature of exceeding 600° C., the silicon nitride film 15 well prevents oxidants such as oxygen from penetrating into the high-dielectric-constant metal oxide film 3. As a result, no formation of a silicon oxide or additional growth of the silicon oxide film occurs in the region either on the top or under surface of the high-dielectric-constant metal oxide film 3 and, therefore, a gate insulating film having a thin electrical film thickness of the gate insulating film can be successfully formed.

### Second Embodiment

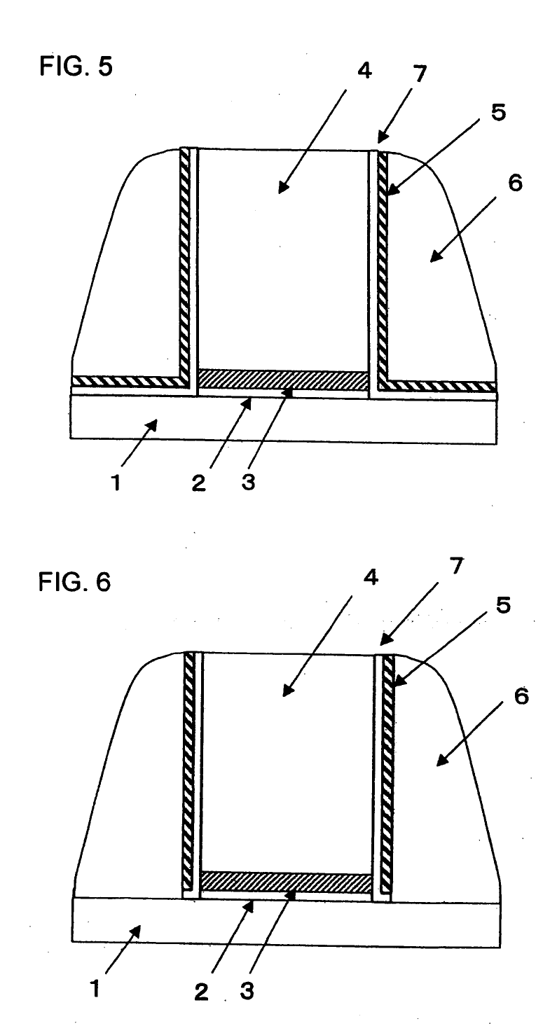

In the present embodiment, as shown in FIG. 5, there are set, on a silicon substrate 1, a gate insulating film in which layers of a silicon containing insulating film 2 and a high-dielectric-constant metal oxide film 3 are laid in this order, a silicon containing gate electrode 4 formed on this gate insulating film, and sidewalls 6 each of which is formed of silicon oxide on a lateral face of this gate electrode, the face of which is perpendicular to the substrate, with a silicon oxide film 7 and a silicon nitride film 5 lying in this order therebetween. Excepting that the silicon oxide films 7 are set, the structure of the present embodiment can be the same as that of First Embodiment.

While the silicon nitride film 5 is laid beneath each sidewall 6 in the structure shown in FIG. 5, it is also possible to have a structure in which no silicon nitride film is present beneath the sidewall (between the sidewall and the silicon substrate) as shown in FIG. 6. Compared with the structure in which the silicon nitride film is in contact with the silicon substrate 1 directly, the structure of the present embodiment in which the silicon oxide film 7 lies between the silicon nitride film 5 and the silicon substrate 1 is more preferable from the point of view of preventing the generation of an interface state.

A MISFET having a structure of the present embodiment can be formed as follows.

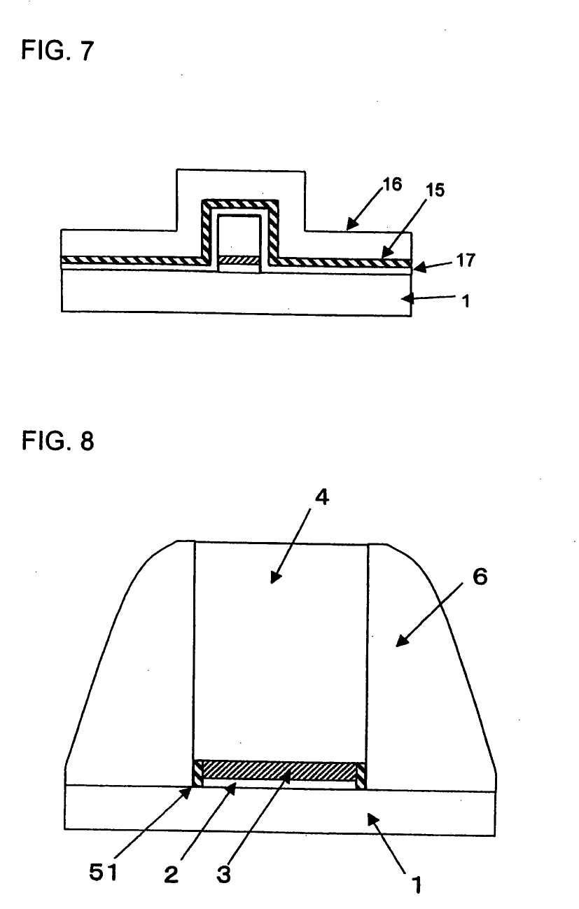

A substrate shown in FIG. 4(f) is fabricated in the same way as the manufacturing method of First Embodiment. Next, after a silicon oxide film 17 of NSG or the like is formed, a silicon nitride film 15 which is to be used as barriers to oxidants and a silicon oxide film 16 of NSG or the like which is to be used as sidewalls are laid in this order (FIG. 7). Hereat, the silicon oxide film 17 is preferably formed at a temperature of not higher than 600° C., from the viewpoint of preventing oxidants such as oxygen from penetrating into the high-dielectric-constant metal oxide film. The formation of a silicon oxide film at such a relatively low temperature can be made well by the AL-CVD (Atomic Layer CVD) method. In respect of the film growth rate and film quality, this film deposition is made at a temperature of preferably not lower than 200° C. and more preferably not lower than 400° C.

Next, an etch back is made by means of anisotropic etching, whereby sidewalls 6 overlying layers of the silicon oxide film 7 and the silicon nitride films 5, being laid in this order, are formed (FIG. 5).

As First Embodiment, in the afore-mentioned steps and the subsequent steps, various treatments according to known methods are carried out, as a prescribed structure requires, and the formation of a MISFET structure may be accomplished.

The silicon oxide film 17 of the present embodiment functions as a buffer film when the silicon nitride film 15 laid thereon is removed by etching, which facilitates to prevent etching to cause damage to the silicon substrate itself. When an excessive etching is made so as to remove the silicon nitride film 15 thoroughly by means of dry etching, the damage to the silicon substrate itself can be well prevented by terminating the etching on the silicon oxide film 17. The silicon oxide film 17 on the surface of the silicon substrate can be selectively removed more easily, using wet etching. In this respect, the thickness of this silicon oxide film 17 is set preferably not less than 1 nm and more preferably not less than 5 nm. Meanwhile, as regarding the throughput, a short deposition time period of the silicon oxide film 17 is preferable so that, in this respect, the thickness of the silicon oxide film 17 is set preferably not greater than 20 nm and more preferably not greater than 10 nm.

Further, by forming a silicon oxide film 17 and a silicon nitride film 15 and performing an etch back by means of anisotropic etching first and thereafter forming a silicon oxide film 16 for sidewalls and applying another etch back to this film, such a structure as shown in FIG. 6, in which silicon nitride films are absent beneath the sidewalls, can be formed.

### Third Embodiment

In the present embodiment, as shown in FIG. 8, there are set, on a silicon substrate 1, a gate insulating film in which layers of a silicon containing insulating film 2 and a high-dielectric-constant metal oxide film 3 are laid in this order, a silicon containing gate electrode 4 formed on this gate insulating film, silicon nitride films 51 (nitrogen-containing sections) each of which is formed selectively and directly on a lateral face of this gate insulating film and sidewalls 6 each of which is formed of silicon oxide on a lateral face of this gate electrode, the face of which is perpendicular to the substrate and includes the surface of this silicon nitride film 51. Each silicon nitride film 51 covers the internal faces of a recess that is formed with respect to the plane of a lateral face of the gate electrode, so as to fill up the recess. The thickness of these silicon nitride films 51 may be set appropriately within a range enough to provide the barrier function against the oxidants such as oxygen and, for instance, in a range of 0.5 nm to 10 nm. If the film is too thin, sufficient barrier function cannot be obtained. Further, since the thickness of these silicon nitride films 51 corresponds to the depth of the recesses in fabrication, it is preferable to set a necessary and sufficient thickness as the size of the high-dielectric-constant metal oxide film in the direction of the gate length is limited.

A MISFET having a structure of the present embodiment can be formed as follows.

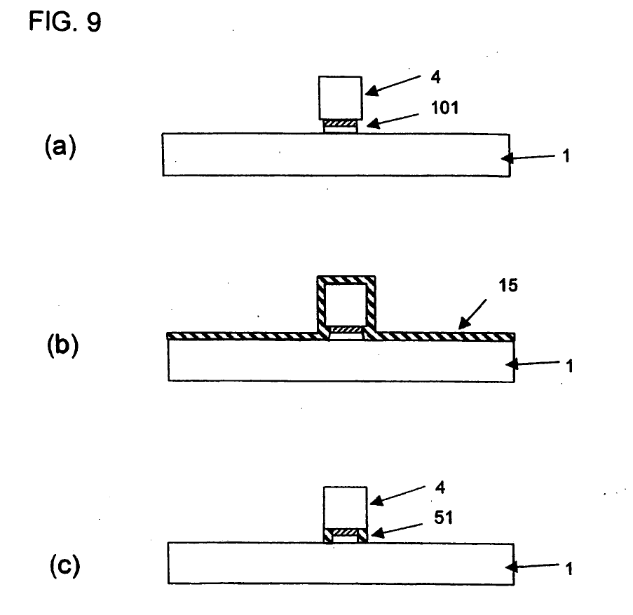

A substrate shown in FIG. 4(e) is fabricated in the same way as the manufacturing method of First Embodiment. Next, after the resist pattern 21 is removed with a resist remover, the HfSiO film 13 (or the HfSiON film) and the thermal oxidation film 12 other than their sections lying beneath the gate electrode are removed with an insulating-film removing agent, and thereby a gate insulating film with a layered structure made of a silicon containing insulating film 2 (the thermal oxidation film) and a high-dielectric-constant metal oxide film 3 (the HfSiO film or the HfSiON film) is formed. Thereat, with the removing agent composition, the treatment time period and such being set appropriately, side etch is applied to the gate insulating film (at least the HfSiO film 3 or the HfSiON film) lying beneath the gate electrode to form recesses 101 with respect to the plane of respective lateral faces of the gate electrode (FIG. 9(a)). The amount of this side etch is arranged appropriately depending on the thickness of the silicon nitride films 51 that are to be formed subsequently. This step of removing the film along with side etching may be performed, for example, under the following conditions. The conditions of removing the insulating film: An immersion in an aqueous solution of hydrofluoric acid (HF:H₂O=1:600 (weight ratio)) at 28° C. for a time period of 3 minutes.

Next, a silicon nitride film 15 which is to serve as a barrier to oxidants is laid so as to fill the recesses 101 (FIG. 9(b)). Next, by performing dry etching, the portions of the silicon nitride film lying on the gate electrode and the silicon substrate are removed, and then wet etching is applied thereto so that the silicon nitride film 15 may remain within the recesses 101 (FIG. 9(c)). The wet etching hereat may be carried out, for example, under the following conditions.

The conditions of wet etching: An immersion in phosphoric acid at 160° C. for a time period of 1 minute.

As described above, silicon nitride films 51 are set selectively and directly on lateral faces of the gate insulating film (at least the high-dielectric-constant metal oxide film), and following that, a prescribed MISFET structure may be formed in the same way as First Embodiment.

In the present embodiment, because a silicon oxide film 16 which is to be used as sidewalls is formed after silicon nitride films 51 which are to be used as barriers to oxidants are formed, even if the deposition in the step of growing the silicon oxide film is carried out in an environment that is set, from the viewpoints of the film growth rate and film quality, to have a relatively high temperature exceeding 600° C., the silicon nitride films 51 well prevent oxidants such as oxygen from penetrating into the high-dielectric-constant metal oxide film 3. As a result, no formation of a silicon oxide or additional growth of the silicon oxide film occurs in the region either on the top or under surface of the high-dielectric-constant metal oxide film 3 and, therefore, a gate insulating film having a thin electrical film thickness of the gate insulating film can be successfully formed.

### Fourth Embodiment

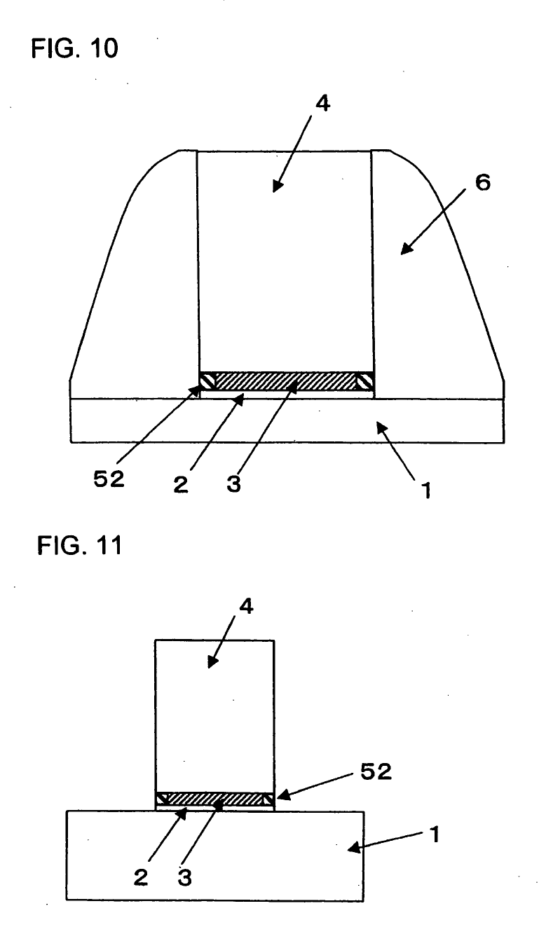

In the present embodiment, as shown in FIG. 10, there are set, on a silicon substrate 1, a gate insulating film in which layers of a silicon containing insulating film 2 and a high-dielectric-constant metal oxide film 3 are laid in this order, a silicon containing gate electrode 4 formed on this gate insulating film, and sidewalls 6 each of which is formed of silicon oxide on a lateral face of the gate electrode, the face of which is perpendicular to the substrate and includes a lateral face of this gate insulating film. In addition, the high-dielectric-constant metal oxide film 2 has a nitridation region 52 (nitrogen containing section) on each of its lateral face sides. In the case that a nitrogen containing metal oxide film of HfSiON or such is used as the high-dielectric-constant metal oxide film 2, there are formed on the lateral face sides the nitridation regions having a higher nitrogen content than the central section of the film in the direction parallel to the substrate plane. The thickness of these nitridation regions 52 (the length in the direction of the gate length from the lateral face) may be set appropriately within a range possible to provide the barrier function against the oxidants such as oxygen and, for instance, the thickness of the regions, wherein the nitrogen content (the ratio of the number of nitrogen atoms to the number of the whole constitutive atoms (percentage)) is not less than 5%, may be set in a range of 1 nm to 20 nm. If the nitridation regions are too thin, the sufficient barrier function cannot be obtained. If too thick, on the other hand, a lowering of the reliability and a reduction of efficiency for the nitriding treatment may result, and hence it is preferable to set a necessary and sufficient thickness. Further, in respect of the barrier function, the nitrogen content in these nitridation regions is set preferably not less than 5% and more preferably not less than 10%. Meanwhile, in respect of the reliability and efficiency for the nitriding treatment, it is set preferably not higher than 50% and more preferably not higher than 40%.

A MISFET having a structure of the present embodiment can be formed as follows.

A substrate shown in FIG. 4(f) is fabricated in the same way as the manufacturing method of First Embodiment, and is subjected to a nitriding treatment so that the afore-mentioned regions 52 may be formed therein. This nitriding treatment may be carried out by the heat treatment in an ammonia atmosphere or the plasma nitriding treatment using a nitrogen containing gas such as N₂ or NO. For example, by applying a nitriding treatment under the following conditions of the nitriding treatment to a HfSiO film (Si mole ratio: 30%), nitridation regions with a thickness of 3.5 nm or so wherein the nitrogen content is not less than 5% and the maximum nitrogen content is 15% can be formed.

The conditions of the nitriding treatment: In an ammonia atmosphere, at 760 Torr, at 800° C. and for 30 minutes.

After the nitridation regions 52 are formed on both lateral face sides of the high-dielectric-constant metal oxide film (the HfSiO film) as described above, a prescribed MISFET structure may be formed as First Embodiment.

Hereat, the exposed faces of the gate electrode 4 and the silicon containing insulating film 2 are also nitrided by this nitriding treatment. Nevertheless, since the high-dielectric-constant metal oxide film of HfSiO or the like has a high gas permeability, the nitridation regions formed therein are thicker than those formed in the gate electrode or the silicon containing insulating film.

In the present embodiment, because a silicon oxide film 16 which is to be used as sidewalls is formed after nitridation regions 52 are formed on both lateral face (exposed face) sides of the high-dielectric-constant metal oxide film, even if the deposition in the step of growing the silicon oxide film is carried out in an environment that is set, from the viewpoints of the film growth rate and film quality, to have a relatively high temperature exceeding 600° C., the nitridation regions 52 well prevent oxidants such as oxygen from penetrating into the high-dielectric-constant metal oxide film 3. As a result, no formation of a silicon oxide or additional growth of the silicon oxide film occurs in the region either on the top or under surface of the high-dielectric-constant metal oxide film 3 and, therefore, a gate insulating film having a thin electrical film thickness of the gate insulating film can be successfully formed.

### Fifth Embodiment

The main features characterizing the present embodiment are that after a gate electrode and a gate insulating film comprising a high-dielectric-constant metal oxide film are formed, while the high-dielectric-constant metal oxide film is exposed, a treatment that is conducted under heating in an oxidizing atmosphere, that is, the deposition of a silicon oxide film which is to be used as sidewalls is performed at a temperature of not higher than 600° C.

A substrate shown in FIG. 4(f) is fabricated in the same way as the manufacturing method of First Embodiment. Next, a silicon oxide film 16 of NSG or the like which is to be used as sidewalls is grown over the entire surface at a temperature of not higher than 600° C. By carrying out the deposition at or below 600° C., the penetration of oxidants such as oxygen into the high-dielectric-constant metal oxide film can be well prevented. Hereat, the use of the AL-CVD (Atomic Layer CVD) method can provide excellent film deposition. In respect of the film growth rate and film quality, the temperature therefor is set preferably not lower than 200° C. and more preferably not lower than 400° C. After that, the silicon oxide film 16 is etched back, and thereby sidewalls are formed.

After sidewalls are set as described above, a prescribed MISFET structure may be formed in the same way as First Embodiment.

In any one of the afore-mentioned manufacturing methods of First to Fifth Embodiments, a structure in which a silicon nitride film is laid between the high-dielectric-constant metal oxide film (the HfSiO film or the HfSiON film) 3 and the gate electrode 4 can be formed by forming a silicon nitride film on the HfSiO film 13 (or the HfSiON film) and then forming a polysilicon film 14 thereon.

1. A semiconductor device comprising a MIS type field effect transistor, wherein the transistor comprising:
a silicon substrate;
a gate insulating film comprising a high-dielectric-constant metal oxide film and a silicon containing insulating film lying between the metal oxide film and the silicon substrate;
a silicon containing gate electrode formed on the gate insulating film; and
a sidewall including silicon oxide as a constituting material, which is formed on each lateral face side of the gate electrode; and
wherein a silicon nitride film is interposed between the sidewall and at least the lateral face of the gate electrode, and
wherein the silicon nitride film covers the lateral face of the high-dielectric-constant metal oxide film, and a silicon oxide film underlies the silicon nitride film.

2. The semiconductor device comprising the MIS type field effect transistor according to claim 1, wherein the silicon nitride film is laid between the sidewall and the silicon substrate.

3. The semiconductor device comprising the MIS type field effect transistor according to claim 1, wherein the silicon nitride film is absent between the sidewall and the silicon substrate.

4. A semiconductor device comprising a MIS type field effect transistor, wherein the transistor comprising:
a silicon substrate;
a gate insulating film comprising a high-dielectric-constant
metal oxide film and a silicon containing insulating film lying between the metal oxide film and the silicon substrate; and
a silicon containing gate electrode formed on the gate insulating film; and
wherein the high-dielectric-constant metal oxide film has a nitrogen containing section at least on each of its lateral face sides.

5. The semiconductor device according to claim 4, wherein the nitrogen-containing section is a silicon nitride film covering at least the lateral face of the high-dielectric-constant metal oxide film.

6. The semiconductor device according to claim 5, wherein each lateral face of the gate insulating film has a recess with respect to the plane of the lateral face of the gate electrode, and, inside the recess, the silicon nitride film covers at least the lateral face of the high-dielectric-constant metal oxide film.

7. The semiconductor device according to claim 4, wherein the nitrogen containing section is formed by applying a nitriding treatment to each lateral face section of the high-dielectric-constant metal oxide film.

8. The semiconductor device according to claim 4, further comprising a sidewall including silicon oxide as a constituting material, which is formed on each lateral face side of the gate electrode.

9. The semiconductor device according to claim 1, wherein a silicon nitride film is laid between the high-dielectric-constant metal oxide film and the gate electrode.

10. The semiconductor device according to claim 1, wherein the high-dielectric-constant metal oxide film contains hafnium (Hf).

11. The semiconductor device according to claim 1, wherein a dielectric constant of the high-dielectric-constant metal oxide film is not less than 10.

12. The semiconductor device according to claim 1, wherein the high-dielectric-constant metal oxide film is absent beneath the sidewall.

13. The semiconductor device according to claim 1, wherein a gate length of the gate electrode is not greater than 1 μm.

14. (canceled)

15. (canceled)

16. A method of manufacturing a semiconductor device comprising the steps of:
forming a high-dielectric-constant metal oxide film over a silicon substrate after forming a silicon containing insulating film;
forming a film of a silicon containing gate electrode material over the high-dielectric-constant metal oxide film;
forming a gate electrode by patterning the film of a gate electrode material;
forming a pattern of the high-dielectric-constant metal oxide film and the silicon containing insulating film under the gate electrode by patterning the high-dielectric-constant metal oxide film and the silicon containing insulating film;
forming a first silicon oxide film over the entire surface at a temperature of not higher than 600° C.;
forming a silicon nitride film on the first silicon oxide film;
forming a second silicon oxide film on the silicon nitride film; and
etching back the second silicon oxide film, the silicon nitride film and the first silicon oxide film and thereby forming a sidewall on each lateral face of the gate electrode with the first silicon oxide film and the silicon nitride film lying therebetween.

17. The method of manufacturing a semiconductor device according to claim 16, further comprising, after the step of forming the silicon nitride film, the step of applying etch back to the silicon nitride film and the first silicon oxide film so that the silicon nitride film and the silicon oxide film lying on the gate electrode and the silicon substrate can be removed, following which the second silicon oxide film is formed over the entire surface and by etching back the second silicon oxide film, a sidewall is formed on each lateral face of the gate electrode.

18. A method of manufacturing a semiconductor device comprising the steps of:
forming a high-dielectric-constant metal oxide film over a silicon substrate after forming a silicon containing insulating film;
forming a film of a silicon containing gate electrode material over the high-dielectric-constant metal oxide film;
forming a gate electrode by patterning the film of a gate electrode material;
forming a pattern of the high-dielectric-constant metal oxide film under the gate electrode by patterning the high-dielectric-constant metal oxide film;
removing at least each lateral face section of the pattern of the high-dielectric-constant metal oxide film by means of isotropic etching to form a recess;
forming a silicon nitride film over the entire surface so as to fill up the recess;
etching the silicon nitride film in such a way that, inside the recess, at least the silicon nitride film covering each lateral face of the high-dielectric-constant metal oxide film can remain; and
forming a silicon oxide film over the entire surface and then etching back the silicon oxide film, and thereby forming a sidewall on each lateral face of the gate electrode.

19. A method of manufacturing a semiconductor device comprising the steps of:
forming a high-dielectric-constant metal oxide film over a silicon substrate after forming a silicon containing insulating film;
forming a film of a silicon containing gate electrode material over the high-dielectric-constant metal oxide film;
forming a gate electrode by patterning the film of a gate electrode material;
forming a pattern of the high-dielectric-constant metal oxide film under the gate electrode by patterning the high-dielectric-constant metal oxide film;
applying a nitriding treatment to each lateral face section of the pattern of the high-dielectric-constant metal oxide film; and
forming a silicon oxide film over the entire surface and then etching back the silicon oxide film, and thereby forming a sidewall on each lateral face of the gate electrode.

20. A method of manufacturing a semiconductor device comprising the steps of:
forming a high-dielectric-constant metal oxide film over a silicon substrate after forming a silicon containing insulating film;
forming a film of a silicon containing gate electrode material over the high-dielectric-constant metal oxide film;
forming a gate electrode by patterning the film of a gate electrode material;
forming a pattern of the high-dielectric-constant metal oxide film under the gate electrode by patterning the high-dielectric-constant metal oxide film;
forming a silicon oxide film over the entire surface at a temperature of not higher than 600° C.; and
etching back the silicon oxide film, and thereby forming a sidewall on each lateral face of the gate electrode.

21. The method of manufacturing a semiconductor device according to claim 18, wherein a pattern of the silicon containing insulating film is further formed under the gate electrode by patterning the silicon containing insulating film.

22. The method of manufacturing a semiconductor device according to claim 16, wherein the high-dielectric-constant metal: oxide film contains hafnium (Hf).

23. The method of manufacturing a semiconductor device according to claim 16, wherein a dielectric constant of the high-dielectric-constant metal oxide film is not less than 10.

24. The method of manufacturing a semiconductor device according to claim 16, wherein a gate length of the gate electrode is not greater than 1 μm.

25. The semiconductor device according to claim 1, wherein a thickness of the silicon oxide film is within a range of 1 to 20 nm.

26. The semiconductor device according to claim 1, wherein a thickness of the silicon oxide film is within a range of 5 to 10 nm.

27. The semiconductor device according to claim 1, wherein a thickness of the silicon nitride film is within a range of 1 to 10 nm.

28. The semiconductor device according to claim 1, wherein the high-dielectric-constant metal oxide film has a nitridation region on each of its lateral face sides.

29. The semiconductor device according to claim 1, wherein the nitridation region is formed within a range of 1 to 20 nm in the direction from its lateral face to inside of the gate electrode, and a nitrogen content in the region is not less than 5%.

30. The semiconductor device according to claim 1, wherein the nitridation region is formed within a range of 1 to 20 nm in the direction from its lateral face to inside of the gate electrode, and a nitrogen content in the region is not less than 10%.

31. The method of manufacturing a semiconductor device according to claim 16, wherein a temperature for forming the first silicon oxide film is within a range of 200 to 600° C.

32. The method of manufacturing a semiconductor device according to claim 16, wherein a temperature for forming the first silicon oxide film is within a range of 400 to 600° C.

33. The semiconductor device according to claim 4, wherein a silicon nitride film is laid between the high-dielectric-constant metal oxide film and the gate electrode.

34. The semiconductor device according to claim 4, wherein the high-dielectric-constant metal oxide film contains hafnium (Hf).

35. The semiconductor device according to claim 4, wherein a dielectric constant of the high-dielectric-constant metal oxide film is not less than 10.

36. The semiconductor device according to claim 4, wherein a gate length of the gate electrode is not greater than 1 μm.

37. The method of manufacturing a semiconductor device according to claim 19, wherein a pattern of the silicon containing insulating film is further formed under the gate electrode by patterning the silicon containing insulating film.

38. The method of manufacturing a semiconductor device according to claim 20, wherein a pattern of the silicon containing insulating film is further formed under the gate electrode by patterning the silicon containing insulating film.

39. The method of manufacturing a semiconductor device according to claim 18, wherein the high-dielectric-constant metal oxide film contains hafnium (Hf).

40. The method of manufacturing a semiconductor device according to claim 19, wherein the high-dielectric-constant metal oxide film contains hafnium (Hf).

41. The method of manufacturing a semiconductor device according to claim 20, wherein the high-dielectric-constant metal oxide film contains hafnium (Hf).

42. The method of manufacturing a semiconductor device according to claim 18, wherein a dielectric constant of the high-dielectric-constant metal oxide film is not less than 10.

43. The method of manufacturing a semiconductor device according to claim 19, wherein a dielectric constant of the high-dielectric-constant metal oxide film is not less than 10.

44. The method of manufacturing a semiconductor device according to claim 20, wherein a dielectric constant of the high-dielectric-constant metal oxide film is not less than 10.

45. The method of manufacturing a semiconductor device according to claim 18, wherein a gate length of the gate electrode is not greater than 1 μm.

46. The method of manufacturing a semiconductor device according to claim 19, wherein a gate length of the gate electrode is not greater than 1 μm.

47. The method of manufacturing a semiconductor device according to claim 20, wherein a gate length of the gate electrode is not greater than 1 μm.
